(19) United States
(12) Patent Application Publication
(10) Pub. No.: US 2003/0211640 A1
(43) Pub. Date: Nov. 13, 2003

(54) Method and system for maintenance of semiconductor manufacturing

(75) Inventor: Junji Orimoto, Kanagawa (JP)

Correspondence Address: McGinn & Gibb, PLLC, Suite 200, 8321 Old Courthouse Road, Vienna, VA, 22182-3817, US

(73) Assignee: NEC Electronics Corporation, Kanagawa (JP)

(21) Appl. No.: 10/431,612

(22) Filed: May 8, 2003

(30) Foreign Application Priority Data
May 8, 2002 (JP) 2002-132837

(51) Int. Cl. H01L 21/00; H01L 21/66; G01R 31/26; H01L 21/64

(52) U.S. Cl. 438/14; 438/5; 29/25.01

(57) ABSTRACT

A system is provided for maintaining plural different process flows for manufacturing different kinds of semiconductor device respectively on a semiconductor production line. The plural different process flows are registered in an automatic process control system. The system includes a function unit for setting an automatic process control in the automatic process control system based on an automatic process control information for each of the plural different process. The automatic control information for each of the plural different process flows further includes a process flow name, and process names respectively unique to the single process flow.

### BACKGROUND OF THE INVENTION

1. Field of the Invention

The present invention relates to a method and a system for producing semiconductor devices, and more particularly to a method and a system for setting one or more manufacturing conditions for future manufacturing processes, based on data related to past-manufacturing-processes.

All of patents, patent applications, patent publications, scientific articles and the like, which will hereinafter be cited or identified in the present application, will, hereby, be incorporated by references in their entirety in order to describe more fully the state of the art, to which the present invention pertains.

2. Description of the Related Art

The semiconductor manufacturing comprises a production control system and an automatic process control system. The production control system manages manufacturing processes based on states of processing lots and past-history on semiconductor manufacturing lines. The automatic process control system provides different manufacturing processes respectively belonging to different kinds of semiconductor devices.

FIG. 1 is a block diagram illustrative of a conventional configuration of a semiconductor manufacturing system. The semiconductor manufacturing system comprises a semiconductor production control system 101, at least one measuring apparatus 102 for measuring products, at least one manufacturing apparatus 103 for manufacturing semiconductor devices, and at least one automatic process control system 104. Plural sets of the measuring apparatus 102, the manufacturing apparatus 103, the automatic process control system 104 are provided for plural kinds of the semiconductor devices as the products.

The semiconductor production control system 101 sends, to the measuring apparatus 102, measurement-related instructions such as the kind of measurement, the timing of measurement. The measuring apparatus 102 sends one ore more measurement results to the semiconductor production control system 101 and the automatic process control system 104. The semiconductor production control system 101 and the measuring apparatus 102 are operatively coupled to each other. The measuring apparatus 102 and the automatic process control system 104 are also operatively coupled to each other.

The semiconductor production control system 101 also sends, to the manufacturing apparatus 103, the kind of semiconductor device and a manufacturing instruction. Upon receipt of the kind of semiconductor device and the manufacturing instruction from the semiconductor production control system 101, the manufacturing apparatus 103 sends, to the automatic process control system 104, a notice to the effect that the manufacturing apparatus 103 will manufacture the designated kind of semiconductor device. The automatic process control system 104 controls the manufacturing apparatus 103 in the manufacturing processes for manufacturing the designated kind of semiconductor device. The semiconductor production control system 101 and the manufacturing apparatus 103 are operatively coupled to each other. The manufacturing apparatus 103 and the automatic process control system 104 are also operatively coupled to each other.

Setting respective optimum conditions for manufacturing the semiconductor devices have been made at each step of each of a plurality of the automatic process control system 104, or under each maintenance by each of a plurality of separate maintenance systems provided for a plurality of the manufacturing apparatus 103.

It is necessary that the past maintenance system in the semiconductor manufacturing be constructed for each of the plural steps in the automatic process control system 104 or for each of a plurality of the manufacturing apparatus 103. This increases the cost and the time for developments of the respective maintenance systems.

The respective maintenance systems are not operatively coupled to or associated with the semiconductor production control system 101. Even if the respective maintenance systems calculate the respective optimum conditions, it is impossible to allow the semiconductor production control system 101 to utilize the respectively calculated optimum conditions for managing the past-history and controlling the manufacturing processes by the manufacturing apparatus 103.

In the above circumstances, the development of a novel system for maintenance of the semiconductor manufacturing processes free from the above problems is desirable.

### SUMMARY OF THE INVENTION

Accordingly, it is an object of the present invention to provide a novel system for maintenance of the semiconductor manufacturing processes free from the above problems.

It is a further object of the present invention to provide a novel system for maintenance of the semiconductor manufacturing processes, wherein the system is suitable for an efficient construction itself.

It is a still further object of the present invention to provide a novel system for maintenance of the semiconductor manufacturing processes, wherein the maintenance system is provided in the automatic process control system, and the maintenance system is operatively coupled to or associated with the semiconductor production control system, thereby to allow the semiconductor production control system to utilize one or more maintenance-system-calculated optimum conditions for managing the past-history and controlling manufacturing processes by the manufacturing apparatus.

It is yet a further object of the present invention to provide a novel method for maintenance of the semiconductor manufacturing processes free from the above problems.

It is a further object of the present invention to provide a novel method for maintenance of the semiconductor manufacturing processes, wherein the method is suitable for an efficient realization itself.

It is a still further object of the present invention to provide a novel method for maintenance of the semiconductor manufacturing processes, wherein the method allows the semiconductor production control system to utilize one or more calculated optimum conditions for managing the past-history and controlling manufacturing processes by the manufacturing apparatus.

The present invention provides a system for maintaining plural different process flows for manufacturing different kinds of semiconductor device respectively on a semiconductor production line. The plural different process flows are registered in an automatic process control system. The system includes: a function unit for setting an automatic process control in the automatic process control system based on an automatic process control information for each of the plural different process. The automatic control information for each of the plural different process flows further includes a process flow name, and process names respectively unique to the single process flow.

The above and other objects, features and advantages of the present invention will be apparent from the following descriptions.

### BRIEF DESCRIPTION OF THE DRAWINGS

Preferred embodiments according to the present invention will be described in detail with reference to the accompanying drawings.

FIG. 1 is a block diagram illustrative of a conventional configuration of a semiconductor manufacturing system.

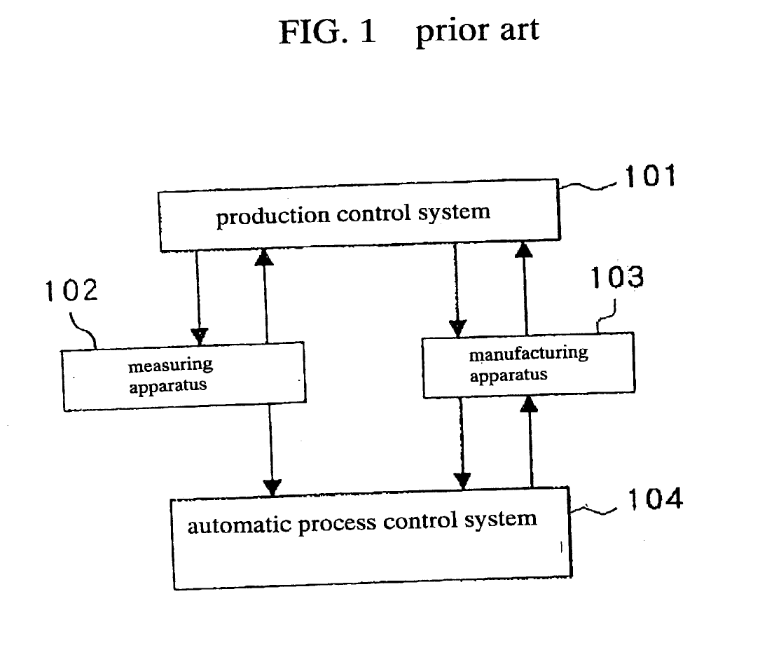

FIG. 2 is a block diagram illustrative of a novel configuration of a semiconductor manufacturing system in a first embodiment of the present invention.

FIG. 3 is a flow chart illustrative of sequential steps of operations of the maintenance system included in the semiconductor manufacturing system shown in FIG. 2.

FIG. 4 is a diagram illustrative of one typical example of the operations of the semiconductor production control system and the automatic process control system included in the manufacturing system shown in FIG. 2.

### DETAILED DESCRIPTION OF THE PREFERRED EMBODIMENTS

A first aspect of the present invention is a method of maintaining plural different process flows for manufacturing different kinds of semiconductor device respectively on a semiconductor production line. The plural different process flows are registered in an automatic process control system. The method includes: setting an automatic process control in the automatic process control system based on an automatic process control information for each of the plural different process. The automatic control information for each of the plural different process flows further includes a process flow name, and process names respectively unique to the single process flow.

It is possible that the automatic process control information is supplied to a production control system which manages production processes based on a state of processing lots and a past-history on the semiconductor manufacturing line; and the production control system and the automatic process control system are allowed to function based on the automatic process control information commonly.

A second aspect of the present invention is a system for maintaining plural different process flows for manufacturing different kinds of semiconductor device respectively on a semiconductor production line. The plural different process flows are registered in an automatic process control system. The system includes: a first function unit for setting an automatic process control in the automatic process control system based on an automatic process control information for each of the plural different process, wherein the automatic control information for each of the plural different process flows further includes a process flow name, and process names respectively unique to the single process flow.

It is also possible that the system further includes: a second function unit for supplying the automatic process control information to a production control system which manages production processes based on a state of processing lots and a past-history on the semiconductor manufacturing line; and a third function unit for allowing the production control system and the automatic process control system to function based on the automatic process control information commonly.

A third aspect of the present invention is a semiconductor manufacturing system which includes the following systems. An automatic process control system registers plural different process flows for manufacturing different kinds of semiconductor device respectively on a semiconductor production line. A production control system manages production processes based on a state of processing lots and a past-history on the semiconductor manufacturing line. A maintenance system maintains the plural different process flows registered in the automatic process control system. The maintenance system includes a first function unit for setting an automatic process control in the automatic process control system based on an automatic process control information for each of the plural different process. The automatic control information for each of the plural different process flows further includes a process flow name, and process names respectively unique to the single process flow.

It is possible that the system further includes: a second function unit for supplying the automatic process control information to the production control system; and a third function unit for allowing the production control system and the automatic process control system to function based on the automatic process control information commonly.

The automatic process control is set by the maintenance system for setting the automatic process control in the automatic process control system based on the automatic process control information for each of the plural different process, wherein the automatic control information for each of the plural different process flows further includes the process flow name, and the process names respectively unique to the single process flow. This maintenance system is usable commonly to all of the processes and all of the systems and apparatuses.

The automatic process control informations are supplied not only to the automatic process control system but also the production control system, so as to allow the production control system to manage the history and to perform the process control under an optimum condition calculated by the maintenance system.

The following embodiments are typical examples for practicing the foregoing aspects of the present invention. Although the subject matters of the present invention have been described in details, the following additional descriptions in one or more typical preferred embodiments or examples will be made with reference to the drawings for making it easy to understand the typical modes for practicing the foregoing aspects of the present invention.

First Embodiment

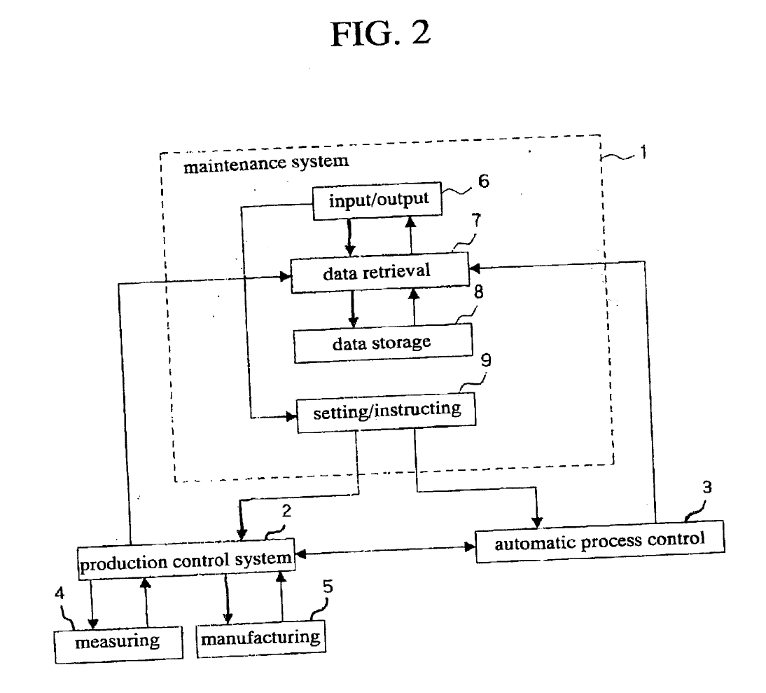

A first embodiment according to the present invention will be described in detail with reference to the drawings. FIG. 2 is a block diagram illustrative of a novel configuration of a semiconductor manufacturing system in a first embodiment of the present invention. The semiconductor manufacturing system may include a maintenance system 1, a semiconductor production control system 2, an automatic process control system 3, a measuring apparatus 4 for measuring products, and a manufacturing apparatus 5 for manufacturing products. The semiconductor production control system 2 stores one or more product-process conditions and operates in accordance with both the stored one or more product-process conditions and one or more predetermined control programs. The product-process conditions may include, but not limited to, at least one of product name, process-flow name, process name, and product-process conditions, wherein each of those names may preferably comprise alphanumeric characters. The automatic process control system 3 stores a variety of informations and calculates one or more process conditions based on the stored informations.

The semiconductor production control system 2 and the maintenance system 1 are operatively coupled to each other. The semiconductor production control system 2 and the measuring apparatus 4 are operatively coupled to each other. The semiconductor production control system 2 and the manufacturing apparatus 5 are operatively coupled to each other. The semiconductor production control system 2 and the automatic process control system 3 are operatively coupled to each other. The automatic process control system 3 and the maintenance system 1 are operatively coupled to each other.

The maintenance system 1 may include an input/output unit 6, a data retrieval unit 7, a data storage unit 8, and a setting/instructing unit 9. The input/output unit 6 and the data retrieval unit 7 are operatively coupled to each other. The input/output unit 6 and the setting/instructing unit 9 are operatively coupled to each other. The data retrieval unit 7 and the data storage unit 8 are operatively coupled to each other. The data retrieval unit 7 and the semiconductor production control system 2 are operatively coupled to each other. The data retrieval unit 7 and the automatic process control system 3 are operatively coupled to each other. The setting/instructing unit 9 and the semiconductor production control system 2 are operatively coupled to each other. The setting/instructing unit 9 and the automatic process control system 3 are operatively coupled to each other.

The outline of operations of the semiconductor manufacturing system will be described. The data retrieval unit 7 retrieves registered process-flow names, registered process names, and past-maintained automatic process control setting informations from the semiconductor production control system 2 and the automatic process control system 3. The data retrieval unit 7 sends a retrieval result to the input/output unit 6 to allow the input/output unit 6 to display the retrieval result. The process-flow names and the process names have been registered in the semiconductor production control system 2. The automatic process control setting informations have been registered in the automatic process control system 3.

For each of the process-flow names, each process name and one or more measurement item names belonging to the each process name are stored in the form of key names in the data storage unit 8. Those informations are renewed in accordance with an instruction by the setting/instructing unit 9.

The setting/instructing unit 9 sends the semiconductor production control system 2 an instruction which indicates whether or not the process name of the previously registered process-flow name designates a process which is subject to the automatic process control. The setting/instructing unit 9 also sends the automatic process control system 3 another instruction which designates a process-flow name of the process which is subjected to the automatic process control, a control-base process which is the base for the automatic process control, a measurement item name of the controlling process, a control-subject process which is subject to the automatic process control, a control-calculation expression, and a process condition corresponding to the control-calculation expression.

The above-described maintenance system may be realized by any available general-purpose computer system which may include, but not limited, to an input unit, an output unit, a controller and a display.

As described above, the maintenance system 1 includes the input/output unit 6, the data retrieval unit 7, the data storage unit 8, and the setting/instructing unit 9.

The input/output unit 6 serves as an interface to user. The input/output unit 6 may be realized by a key board and a display.

The data retrieval unit 7 retrieves product names, process-flow names, process names, product-process conditions for the processes from the semiconductor production control system 2. Each of those names comprises alphanumeric characters.

The data storage unit 8 temporarily stores informations as set from the input/output unit 6 through the data retrieval unit 7 and sends one or more requested or designated informations to the input/output unit 6 through the data retrieval unit 7.

The setting/instructing unit 9 sends a setting information for automatically setting product-process conditions for producing a product which is subject to the automatic process control to both the semiconductor production control system 2 and the automatic process control system 3.

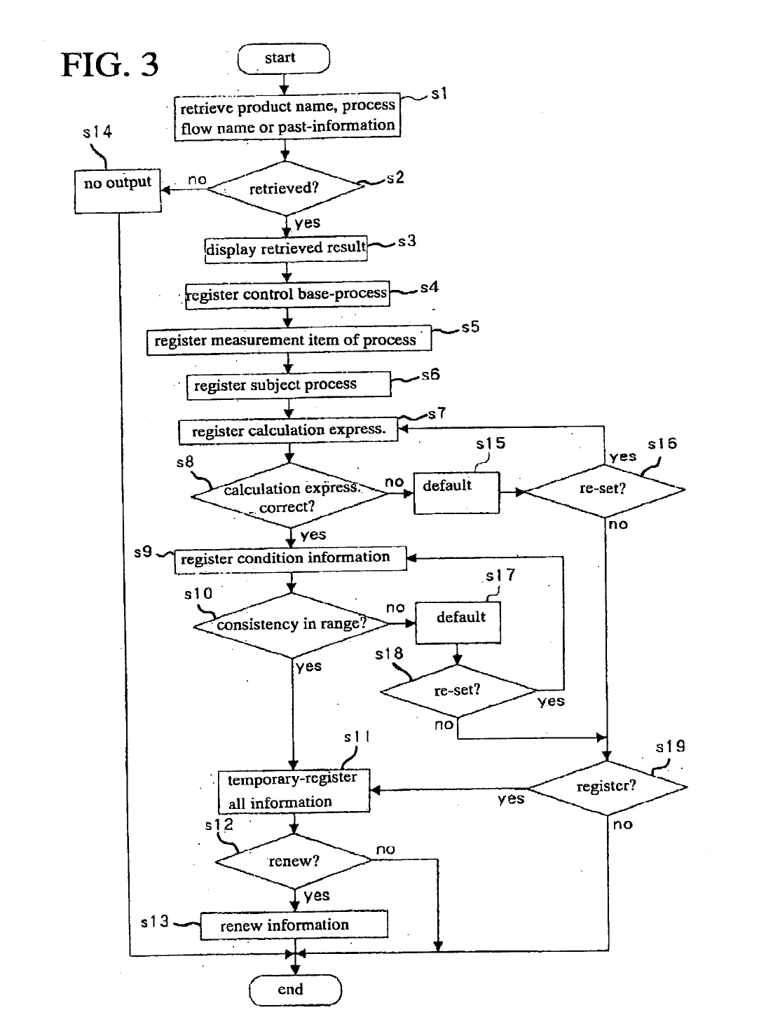

FIG. 3 is a flow chart illustrative of sequential steps of operations of the maintenance system included in the semiconductor manufacturing system shown in FIG. 2. The operations of the maintenance system will be described with reference to FIGS. 2 and 3.

In step S1, entered character strings such as the product names and the process-flow names from the input/output unit 6 are sent to the data retrieval unit 7. The data retrieval unit 7 verifies whether or not any alphanumeric character, which is identical with the entered character or which includes the entered character, has been registered in the semiconductor production control system 2 and the automatic process control system 3.

In step S2, if the data retrieval unit 7 could not retrieve such alphanumeric character as registered in the semiconductor production control system 2 and the automatic process control system 3, then in step S14, the data retrieval unit 7 sends the input/output unit 6 to the effect that such alphanumeric character has not been registered in the semiconductor production control system 2 and the automatic process control system 3.

If the entered character string is not registered in both the semiconductor production control system 2 and the automatic process control system 3, then this means the character entry is default.

If the entered character string is registered but only in the semiconductor production control system 2, then this means that a new automatic process control setting information is added.

If the entered character string is registered in both the semiconductor production control system 2 and the automatic process control system 3, then this means that the automatic process control setting information is renewed.

If any product name or any process-flow name, which includes the entered characters, is present in the semiconductor production control system 2, then a list of one or more corresponding product names or process-flow names is displayed on the input/output unit 6. Thereafter, a selecting instruction or command, which is to select a process-flow name subject to the setting from the list of product names or process-flow names is entered into the input/output unit 6 by user, so that, in step S3, the selected process-flow name, process names belonging to the selected process-flow name, product-process conditions in the process names and a process-flow chart belonging to the selected process-flow name are displayed on the input/output unit 6. If a past-setting information has been registered in the automatic process control system 3, then this past-setting information is also displayed.

In step S4, based on the process-flow name and the process-flow chart displayed on the input/output unit 6, an entry into the input/output unit 6 is made for a command to register or renew the process name of the control-base process which is the base for the automatic process control, to the data storage unit 8.

In step S5, a registration or a change to the data storage unit 8 is made by the input/output unit 6 for the measurement items of the control-base process; for example, the name of a measurement item, which is to be reported to the semiconductor production control system 2 by either the measuring apparatus 4 or the manufacturing apparatus 5, and an adaptable value range of the control-base process which is the base for the automatic process control.

In step S6, another registration or another change to the data storage unit 8 is made by the input/output unit 6 for the name of the control-subject process which is subject to the automatic process control.

In step S7, still another registration or still another renewal to the data storage unit 8 is made by the input/output unit 6 for a control-subject calculating expression.

In step S8, a verification is made by the data storage unit 8, for whether the control-subject calculating expression is correct or incorrect.

If it was verified that the control-subject calculating expression is incorrect, then in step S15, the data storage unit 8 sends the input/output unit 6 a notice to the effect that the control-subject calculating expression is incorrect, and it is verified whether a re-set for the control-subject calculating expression should be made or not. If it was verified that the reset for the control-subject calculating expression should be made, then in step S7, another control-subject calculating expression is reset. If it was verified that the re-set for the control-subject calculating expression should not be made, then in step S19, it is further verified whether the original incorrect control-subject calculating expression should be registered temporarily.

If it was verified that the control-subject calculating expression is correct, then in step S9, the registration or the change to the data storage unit 8 is made by the input/output unit 6 for control-subject condition informations.

In step S10, the data storage unit 8 verifies whether or not the control-subject condition information is within an acceptable range.

If the control-subject condition information is beyond the acceptable range, then in step S17, the data storage unit 8 sends the input/output unit 6 a notice to the effect that the control-subject condition information is default, and in step S18, it is verified whether a re-set for the control-subject condition information should be made or not. If it was verified that the re-set for the control-subject condition information should be made, then in step S9, another control-subject condition information is reset. If it was verified that the re-set for the control-subject condition information should not be made, then in step S19, it is further verified whether the original incorrect control-subject condition information should be registered temporarily.

If in step S10 it was verified that the control-subject condition information is correct, and in step S19 it was verified that the control-subject condition information should be registered temporarily, then in step S11, an entirety of the control informations is registered temporarily.

In step S12, it is verified whether the control information should be renewed.

If in step S12, it was verified that the control information should be renewed, then in step S13, the control information is renewed, and the operation is ended.

As described above, the registration and change of the automatic process control information for the automatic process control are made, and the renewal instruction is made through the input/output unit 6, and the renewal information is sent from the setting/instructing unit 9 to the semiconductor production control system 2 and the automatic process control system 3.

The semiconductor production control system 2 receives informations about whether the process names in the existent process-flow name subject to the automatic process control are subject to the automatic process control. The automatic process control system 3 receives all automatic process control informations including the process-flow name of the process-flow subject to the automatic process control, the control-base process, the measurement item name of the control-base process, the acceptable value range for the measurement item name, the control-subject process, the control calculation expression and the product-process conditions based on the result of the control calculation.

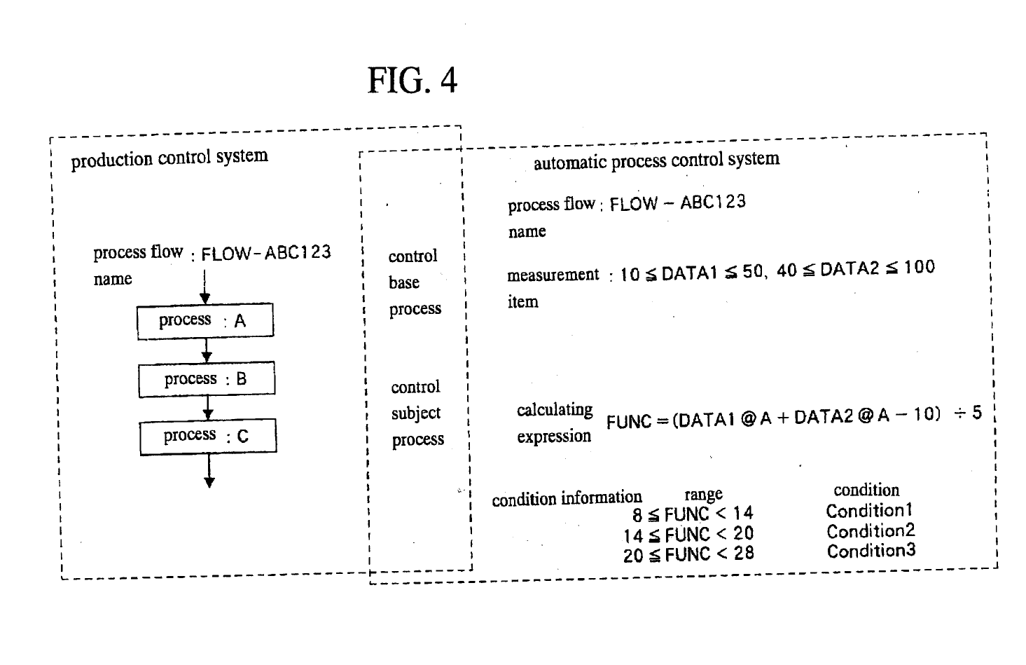

FIG. 4 is a diagram illustrative of one typical example of the operations of the semiconductor production control system 2 and the automatic process control system 3 included in the manufacturing system shown in FIG. 2, wherein a maintenance is made to the automatic process control information.

A process-flow name “FLOW*” is entered through the input/output unit 6. The data retrieval unit 7 retrieves process-flow names which have head characters “FLOW” from the semiconductor production control system 2. The data retrieval unit 7 sends the retrieved process-flow names to the input/output unit 6, so that the user selects a process-flow name which is subject to the automatic process control, from the lest of the retrieved process-flow names, in steps S1 and S2. If any information about the already selected process reflow name is present in the automatic process control system 3, then this information is also displayed together with the retrieved process-flow names on the input/output unit 6 in step S3.

It is possible for registrations of the control-base process and the control-subject process that the process names “A”, “B” and “C” are directly entered through the input/output unit 6. It is also possible that the registrations of the control-base process and the control-subject process are made by mouse-dragging and dropping operations, because the process names “A”, “B” and “C” of the process-flow name “FLOW-ABC123” are displayed as shown in FIG. 4, in steps S4 and S6.

Registration of the measurement item names of the control-base processes may be made by direct entries of “DATA1” and “DATA2” through the input/output unit 6. At this time, further the acceptable ranges for the control-base process is entered.

Registration of the control-subject calculating expression may be made by direct entries of “DATA1@A” and “DATA2@A” through the input/output unit 6, wherein the character after “@” is the variable which indicates the process name. The control-subject calculating expression may be set freely, for example, by using the four fundamental rules of arithmetic and brackets “(” and “)” in step S7. At this time, further, a check in the fundamental rule to the control-subject calculating expression may be made in step S8. For example, it is verified whether the same number of “(” and “)” is used in the control-subject calculating expression, or any overlap of the four fundamental rules of arithmetic is present in the control-subject calculating expression.

Registration of the control-subject condition informations may be made by designating a product condition, to which the change is made, based on the range of resulting values of the control-subject calculating expression. At this time, further it is verified whether the resulting values of the control-subject calculating expression are free of any overlap and are continuous in steps S9 and S10.

The renewal of the automatic process control information is made by designating, through the input/output unit 6, the control-subject calculating expression, which is to be renewed, and defining a combination of the control-base process and the control-subject process in steps S12 and S13, because the control-base process may be grasped as the variables in the control-subject calculating expression.

In this embodiment, the single control-base process is designated. It is, however, possible to designate a plurality of control-base process by combinations of the process names and the measurement item names because in the control-subject calculating expression, the measurement item of the control-base process is designated in the form of “measurement item name @ process name”.

In this embodiment, two measurement item names for the control-base process are used. This novel maintenance system does not limit the number of the measurement item names for the control-base process.

In this embodiment, three kinds of the product-process conditions are used for the control-subject condition informations. This novel maintenance system does not limit the number of the kinds of the product-process conditions for the control-subject condition informations.

This novel maintenance system does not limit the number of the manufacturing apparatus and the kinds of the manufacturing apparatus.

In this embodiment, the single combination of the control-base process and the control-subject process is shown over the process-flow. This novel maintenance system does not limit the number of the combination of the control-base process and the control-subject process over the process-flow.

This novel maintenance system does not limit the method of renewal. Not only the renewal to both the control-base process and the control-subject process but also another renewal to only the control-base process are acceptable to the novel maintenance system.

In the above embodiment, the semiconductor production control system 2 and the automatic process control system 3 are separated from each other. This novel maintenance system may be adopted to a single system which exhibits both functions and operations of the semiconductor production control system 2 and the automatic process control system 3.

The above-described novel maintenance system provides the following advantages.

First, it is possible that a single maintenance system is responsible to all the process-flows for the automatic process control, because for each of the process-reflow name or the product name, user is allowed to set the process name, which is unique in the single process flow, the measurement item name, the calculating expression based on the measurement item name, and the conversion process condition based on the calculated result.

Second, the automatic process control information is usable not only to the automatic process control system but also the semiconductor production control system, so that the history of the automatic carrier of the products and the automatic process control is maintained at a single maintenance system, wherein the process flow names and the process names as keys for the automatic process control are stored or held in both the automatic process control system and the semiconductor production control system.

Although the invention has been described above in connection with several preferred embodiments therefor, it will be appreciated that those embodiments have been provided solely for illustrating the invention, and not in a limiting sense. Numerous modifications and substitutions of equivalent materials and techniques will be readily apparent to those skilled in the art after reading the present application, and all such modifications and substitutions are expressly understood to fall within the true scope and spirit of the appended claims.

What is claimed is:

1. A method of maintaining plural different process flows for manufacturing different kinds of semiconductor device respectively on a semiconductor production line, and said plural different process flows being registered in an automatic process control system, said method including:
setting an automatic process control in said automatic process control system based on an automatic process control information for each of said plural different process, and
wherein said automatic control information for each of said plural different process flows further includes a process flow name, and process names respectively unique to the single process flow.

2. The method as claimed in claim 1, further including:
supplying said automatic process control information to a production control system which manages production processes based on a state of processing lots and a past-history on said semiconductor manufacturing line; and
allowing said production control system and said automatic process control system to function based on said automatic process control information commonly.

3. A system for maintaining plural different process flows for manufacturing different kinds of semiconductor device respectively on a semiconductor production line, and said plural different process flows being registered in an automatic process control system, said system including:
a first function unit for setting an automatic process control in said automatic process control system based on an automatic process control information for each of said plural different process, and
wherein said automatic control information for each of said plural different process flows further includes a process flow name, and process names respectively unique to the single process flow.

4. The system as claimed in claim 3, further including:
a second function unit for supplying said automatic process control information to a production control system which manages production processes based on a state of processing lots and a past-history on said semiconductor manufacturing line; and
a third function unit for allowing said production control system and said automatic process control system to function based on said automatic process control information commonly.

5. A semiconductor manufacturing system including:
an automatic process control system which registers plural different process flows for manufacturing different kinds of semiconductor device respectively on a semiconductor production line;
a production control system which manages production processes based on a state of processing lots and a past-history on said semiconductor manufacturing line; and
a maintenance system for maintaining said plural different process flows registered in said automatic process control system,
wherein said maintenance system includes a first function unit for setting an automatic process control in said automatic process control system based on an automatic process control information for each of said plural different process, and
wherein said automatic control information for each of said plural different process flows further includes a process flow name, and process names respectively unique to the single process flow.

6. The system as claimed in claim 5, further including:
a second function unit for supplying said automatic process control information to said production control system; and
a third function unit for allowing said production control system and said automatic process control system to function based on said automatic process control information commonly.
